(19) United States
(12) Patent Application Publication
(10) Pub. No.: US 2014/0293251 A1
(43) Pub. Date: Oct. 2, 2014

(54) Projection System, Lithographic Apparatus, Method of Projecting a Beam of Radiation onto a Target and Device Manufacturing Method

(71) Applicant: ASML Netherlands B.V., Veldhoven (NL)

(72) Inventors: Hans Butler, Best (NL); Robertus Johannes Marinus De Jongh, Eindhoven (NL); Hendrik Koevoets, Mierlo (NL); Marco Hendrikus Hermanu Oude Nijhuis, Eindhoven (NL); Robertus Leonardus Tousain, Eindhoven (NL); Marc Wilhelmus Maria Van Der Wijst, Veldhoven (NL); Cornelius Adrianus Lambertus De Hoon, Best (NL)

(73) Assignee: ASML Netherlands B.V., Veldhoven (NL)

(21) Appl. No.: 14/305,110

(22) Filed: Jun. 16, 2014

Related U.S. Application Data
(63) Continuation-in-part of application No. 13/002,840, filed on Apr. 28, 2011.
(60) Provisional application No. 61/089,820, filed on Aug. 18, 2008.

(51) Int. Cl. G03F 9/00

(52) U.S. Cl. CPC G03F 9/7096
USPC 355/55

(57) ABSTRACT

A projection system is provided that includes a sensor system that measures at least one parameter that relates to the physical deformation of a frame that supports the optical elements within the projection system, and a control system that, based on the measurements from the sensor system, determines an expected deviation of the position of the beam of radiation projected by the projection system that is caused by the physical deformation of the frame.

### BACKGROUND

1. Field

Embodiments of the present invention relate to a projection system, a lithographic apparatus, a method of projecting a beam of radiation onto a target and a method for manufacturing a device.

2. Background

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., including part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”—direction) while synchronously scanning the substrate parallel or anti-parallel to this direction. It is also possible to transfer the pattern from the patterning device to the substrate by imprinting the pattern onto the substrate.

In a lithographic apparatus, a beam of radiation may be patterned by a patterning device which is then projected onto the substrate by a projection system. This may transfer the pattern to the substrate. It will be appreciated that there is a continual drive to improve the performance of lithography apparatus. Consequently, the requirements for the accuracy of performance of the components within a lithography apparatus correspondingly are continually becoming stricter. In the case of a projection system, one measure of the performance of the projection system is the accuracy with which a patterned beam of radiation may be projected onto a substrate. Any deviation in the position of the patterned beam of radiation may result in errors of the pattern to be formed on the substrate, for example, overlay errors, in which one part of a pattern is not correctly positioned relative to another part of a pattern, focus errors and contrast errors.

In order to minimize errors introduced by the projection system, it is necessary to ensure that optical elements within the projection system that are used to direct the patterned beam of radiation are accurately positioned. Therefore, it has previously been known to provide a stiff frame to which each of the optical elements is mounted and to adjust the position of each of the optical elements relative to the frame in order to position correctly the optical elements.

However, even with such a system, small errors may be introduced. With previously known systems, such small errors were not significantly problematic. However, with the continual drive to improve the performance of lithography apparatus, it is desirable to at least reduce all possible sources of error.

### BRIEF SUMMARY

Given the foregoing, what is needed is a projection system, for example, for use within a lithography apparatus, having improved performance.

According to an aspect of the invention, there is provided a projection system, configured to project a beam of radiation. The projection system includes a frame configured to support at least one optical element that is used to direct at least a part of the beam of radiation, a sensor system configured to measure at least one parameter that relates to a displacement of the frame generated by forces applied to the frame during use of the projection system, and a control system configured to determine an expected deviation of the position of the beam of radiation projected by the projection system that is caused by the displacement of the frame using the measurements of the sensor system.

According to an aspect of the invention, there is provided a lithographic projection apparatus that uses a projection system as disclosed above to project a patterned beam onto a substrate.

According to an aspect of the invention, there is provided a method of projecting a beam of radiation onto a target. The method includes directing the beam of radiation using at least one optical element that is supported by a frame, measuring at least one parameter that relates to a displacement of the frame generated by forces applied to the frame while projecting the beam of radiation onto the target, and determining an expected deviation of the position of the beam of radiation that is caused by the displacement of the frame using said measured at least one parameter.

According to an aspect of the invention, there is provided a device manufacturing method comprising projecting a patterned beam of radiation onto a substrate, using a method of projecting a beam of radiation onto a substrate as disclosed above.

### BRIEF DESCRIPTION OF THE DRAWINGS/FIGURES

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention.

FIGS. 2a and 2b depict a problem that may reduce the performance of a projection system.

FIG. 3 depicts an arrangement of a projection system according to an embodiment of the present invention.

FIG. 4 depicts in more detail an arrangement that may be used according to an embodiment of the present invention.

FIGS. 5, 6, 7 and 8 depict details of alternatives arrangements of a projection system that may be used according to embodiments of the present invention.

FIG. 9 depicts a projection system according to embodiments of the present invention.

FIG. 10 depicts a lithographic apparatus according to embodiments of the present invention.

### DETAILED DESCRIPTION

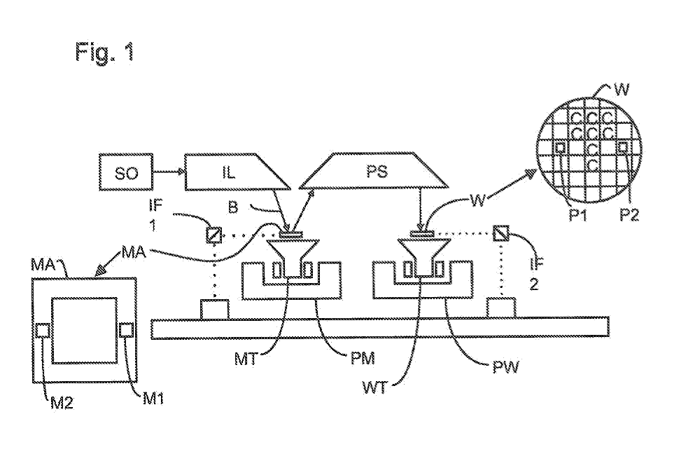

FIG. 1 schematically depicts a lithographic apparatus according to one embodiment of the invention. The apparatus includes:

an illumination system (illuminator) IL configured to condition a radiation beam B (e.g., UV radiation or EUV radiation.

a support structure (e.g., a mask table) MT constructed to support a patterning device (e.g., a mask) MA and connected to a first positioner PM configured to accurately position the patterning device in accordance with certain parameters;

a substrate table (e.g., a wafer table) WT constructed to hold a substrate (e.g., a resist-coated wafer) W and connected to a second positioner PW configured to accurately position the substrate in accordance with certain parameters; and

a projection system (e.g., a refractive projection lens system) PS configured to project a pattern imparted to the radiation beam B by patterning device MA onto a target portion C (e.g., comprising one or more dies) of substrate W.

The illumination system may include various types of optical components, such as refractive, reflective, magnetic, electromagnetic, electrostatic or other types of optical components, or any combination thereof, for directing, shaping, or controlling radiation.

The support structure supports, i.e., bears the weight of, the patterning device.

It holds the patterning device in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a reflective type (e.g., employing a reflective mask). Alternatively, the apparatus may be of a transmissive type (e.g., employing a transmissive mask).

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIG. 1, illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from source SO to illuminator IL with the aid of a beam delivery system BD comprising, for example, suitable directing mirrors and/or a beam expander. In other cases the source may be an integral part of the lithographic apparatus, for example when the source is a mercury lamp. Source SO and illuminator IL, together with beam delivery system BD if required, may be referred to as a radiation system.

Illuminator IL may comprise an adjuster AD for adjusting the angular intensity distribution of the radiation beam. Generally, at least the outer and/or inner radial extent (commonly referred to as a-outer and a-inner, respectively) of the intensity distribution in a pupil plane of the illuminator can be adjusted. In addition, illuminator IL may include various other components, such as an integrator IN and a condenser CO. Illuminator IL may be used to condition the radiation beam, to have a desired uniformity and intensity distribution in its cross-section.

Radiation beam B is incident on the patterning device (e.g., mask MA), which is held on the support structure (e.g., mask table MT), and is patterned by the patterning device. Having traversed mask MA, radiation beam B passes through projection system PS, which focuses the beam onto a target portion C of substrate W. With the aid of second positioner PW and position sensor IF2 (e.g., an interferometric device, linear encoder or capacitive sensor), substrate table WT can be moved accurately, e.g., so as to position different target portions C in the path of radiation beam B. Similarly, first positioner PM and another position sensor IF1 can be used to accurately position mask MA with respect to the path of radiation beam B, e.g., after mechanical retrieval from a mask library, or during a scan. In general, movement of mask table MT may be realized with the aid of a long-stroke module (coarse positioning) and a short-stroke module (fine positioning), which form part of first positioner PM. Similarly, movement of substrate table WT may be realized using a long-stroke module and a short-stroke module, which form part of second positioner PW. In the case of a stepper (as opposed to a scanner) mask table MT may be connected to a short-stroke actuator only, or may be fixed. Mask MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on mask MA, the mask alignment marks may be located between the dies.

The depicted apparatus could be used in at least one of the following modes:

1. In step mode, mask table MT and substrate table WT are kept essentially stationary, while an entire pattern imparted to the radiation beam is projected onto a target portion C at one time (i.e., a single static exposure). Substrate table WT is then shifted in the X and/or Y direction so that a different target portion C can be exposed. In step mode, the maximum size of the exposure field limits the size of target portion C imaged in a single static exposure.

2. In scan mode, mask table MT and substrate table WT are scanned synchronously while a pattern imparted to the radiation beam is projected onto a target portion C (i.e., a single dynamic exposure). The velocity and direction of substrate table WT relative to mask table MT may be determined by the (de-)magnification and image reversal characteristics of projection system PS. In scan mode, the maximum size of the exposure field limits the width (in the non-scanning direction) of the target portion in a single dynamic exposure, whereas the length of the scanning motion determines the height (in the scanning direction) of the target portion.

3. In another mode, mask table MT is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

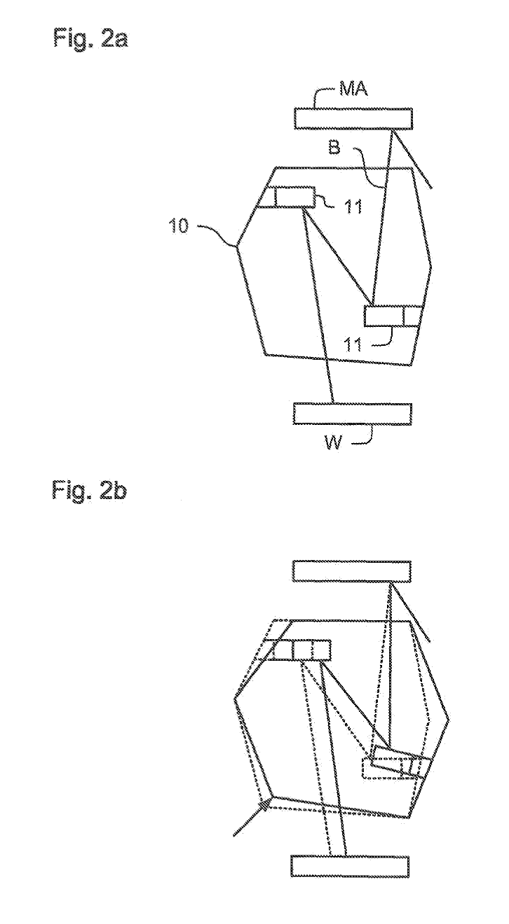

As explained above, and as depicted in FIG. 2a, a projection system may include a relatively stiff frame 10 to which are mounted one or more optical elements 11 for directing a beam of radiation B that has been patterned by a patterning device MA onto a substrate W. Ideally, projection system frame 10 may be accurately positioned within the lithographic apparatus relative to patterning device MA and substrate W and the one or more optical elements 11 may be accurately positioned relative to projection system frame 10, resulting in accurate transfer of the pattern from patterning device MA to substrate W. However, as depicted in FIG. 2b, external forces may act on projection system frame 10, resulting in deformations of the frame. As a result of such deformations, the beam of radiation that is projected onto substrate W may be projected onto the substrate at a location that is slightly shifted from its desired target location. In other words, the beam of radiation that is projected by the projection system may be deviated from an intended radiation beam path. Although, as depicted in FIGS. 2a and 2b, the deformation of the projection system frame 10 may result in a translation of the beam of radiation, the deformation of the projection system frame may, alternatively or additionally, result in other deviations of the projection beam from its desired position. This may result in a deviation of the radiation wavefront at the substrate from that required to form a desired pattern on the substrate, resulting in, for example, focus errors or contrast errors.

It will be appreciated that this problem may be reduced, for example, by increasing the stiffness of the projection system frame 10 such that the external forces acting on the projection system result in smaller deformations of the frame 10 and therefore smaller deviations of the beam of radiation projected by the projection system. However, this may result in an increase in the weight and/or volume of the projection system, which may be undesirable.

A particular problem with the deviation of the position of the projection beam of radiation projected by the projection system caused by deformation of the projection system frame 10 is that it is difficult to measure directly the deviation of the projection beam of radiation during production, namely whilst projecting beams of radiation onto substrates in order to form devices.

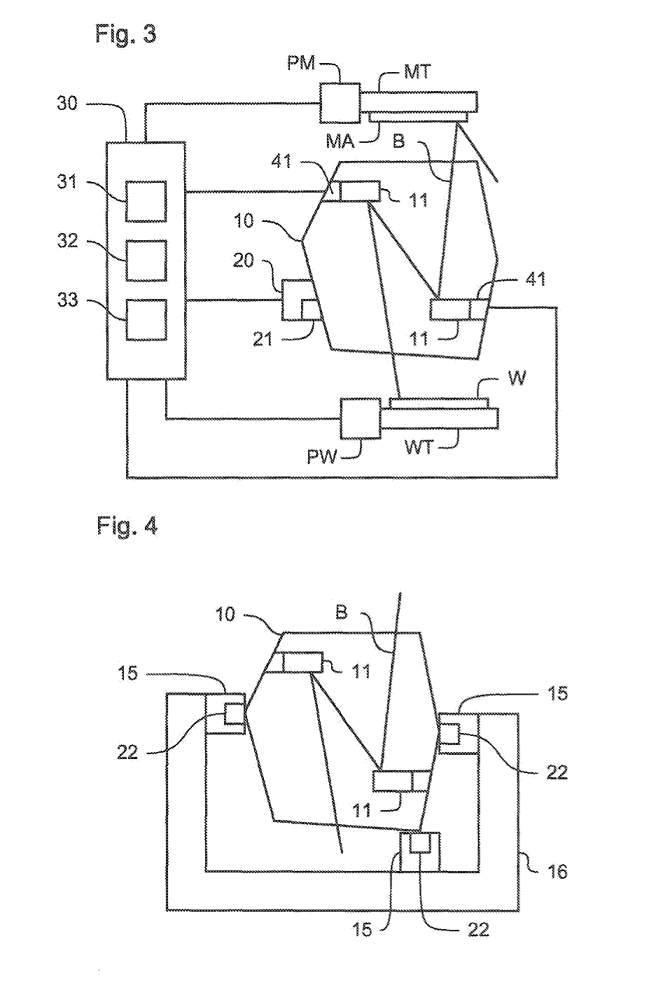

Therefore, according to an embodiment of the present invention, a system such as that schematically depicted in FIG. 3 is provided. As shown, frame 10 of the projection system is provided with a sensor system 20 that measures at least one parameter, discussed further below, that relates to the physical deformation of frame 10 that is generated by the external forces acting on the frame whilst beam of radiation B, that has been patterned by patterning device MA, is projected onto substrate W. A control system 30 is provided that determines, from the measurement data from the sensor system 20, the deviation of beam of radiation B from its intended location that would be caused by the deformation of the frame 10.

The expected deviation determined by control system 30 of beam of radiation B that is, for example, projected onto substrate W, may be used to ameliorate the effects of the deviation caused by the deformation.

For example, as explained in more detail below, one or more corrections may be made based on the expected deviation of beam of radiation B. These corrections compensate for the expected deviation of beam of radiation B from an intended location such that beam of radiation B is more accurately projected onto the desired location of substrate W.

Alternatively, or additionally, the expected deviation may be recorded. This may provide data that is useful, even if no steps are taken to compensate for the expected deviation. For example, by monitoring the expected deviation that is determined by the control system 30, operation of the projection system may continue while the expected deviation is within an acceptable limit but may be suspended if the expected deviation exceeds that limit. Likewise, monitoring of the expected deviation may be used to schedule maintenance operations of the projection system, for example in order to make corrections to the system before the expected deviation exceeds a tolerated extent. Similarly, monitoring the expected deviation of the location of projection beam B from its desired target location on substrate W may be collated for each substrate and/or each device being formed on a substrate, such that the quality of formation of the devices may be graded.

Control system 30 may include a model 31, such as a mathematical model that represents the projection system. In particular, model 31 may relate the parameters measured by sensor system 20 to the deformations of frame 10. In turn, model 31 may relate the deformations of frame 10 to the expected deviation of beam of radiation B projected by the projection system. Accordingly, control system 30 may use a processor 32 and model 31 in order to determine the expected deviation of beam of radiation B projected by the projection system, based on the measurement data from sensor system 20. Processor 32 may then respond in a desired fashion, for example taking steps necessary to compensate for the expected deviation, as explained in more detail below.

Alternatively, or additionally, control system 30 may include a memory 33 containing calibration data. The calibration data may directly relate the measurement data from sensor system 20 to the expected deviation of beam of radiation B projected by the projection system.

For example, the calibration data stored in memory 33 may be generated by performing a series of tests before the projection system is used in, for example, the manufacture of devices. Accordingly, a series of external forces may be applied to the projection system. For each loading condition, measurements may be taken and recorded by the sensor system. At the same time, direct measurements of the deviation of beam of radiation B projected by the projection system may be made. This data may then be used as the calibration data.

It will be appreciated that processor 32 within control system 30 may be configured such that processor 32 can interpolate between sets of calibration data. This may reduce the amount of calibration data that may need to be stored in memory 33. Such an arrangement may be faster to operate than a system including a model 31 such as that discussed above. However, the accuracy of the determination of the expected deviation of beam of radiation B may be limited, for example, by the amount of calibration data stored in memory 33.

In a particular embodiment of a projection system, such that depicted in FIG. 3, sensor system 20 may include one or more accelerometers 21 mounted to frame 10 of the projection system.

The one or more accelerometers 21 may be configured to measure the acceleration of frame 10 of the projection system in, for example, all six degrees of freedom. However, it will be appreciated that this may not be necessary in order to improve the performance of the projection system. Accordingly, the one or more accelerometers 21 may measure the acceleration of the frame 10 in a more limited set of degrees of freedom.

It should also be appreciated that it may be sufficient to configure the one or more accelerometers 21 to monitor the acceleration of a single part of frame 10. Alternatively, however, the accuracy of the determination of the expected deviation of beam of radiation B projected by the projection system may be improved by configuring the one or more accelerometers 21 such that the acceleration of more than one part of the frame 10 is separately monitored.

The measured acceleration of one or more parts of frame 10 of the projection system will be related to the external forces applied to frame 10 and therefore to the deformations that will be induced in frame 10 by those external forces. Accordingly, control system 30 may determine the external forces applied to the projection system based on the measurement data from the one or more accelerometers 21. Controller 30 may then use that force data to determine the expected deviation of beam of radiation B as described above. Such an arrangement may be particularly beneficial for a projection system to be used in a lithographic apparatus in which extreme ultraviolet (EUV) radiation is used to image a pattern onto a substrate. In such apparatus, the projection system is typically arranged in an evacuated chamber in order to minimize absorption of the EUV beam of radiation by gas within the system. In such an arrangement, the only external forces that may be applied to frame 10 of the projection system are transmitted through the mounting points by which the projection system is mounted to the remainder of the lithographic apparatus. For example, other external forces, such as acoustic disturbances transmitted through the gas surrounding the projection system may be eliminated or reduced to an insignificant level. By reducing the possible mechanisms for transmitting external forces to the projection system, it may be relatively straightforward to determine accurately the forces exerted on the projection system that produce the accelerations measured by the one or more accelerometers 21. Accordingly, accurate determinations of the expected deviation of beam of radiation B may be based on the data from the one or more accelerometers 21.

Alternatively or additionally, as depicted in FIG. 4, sensor system 20 may include one or more force sensors 22 that directly measure the force applied between frame 10 of the projection system and mounts 15 by which the projection system may be mounted to an apparatus in which it is to be used.

For example, mounts 15 may be used to mount the projection system to a reference frame 16 within a lithographic apparatus. In particular, sensor system 20 may be arranged such that each of mounts 15 that supports frame 10 of the projection system may be associated with a force sensor 22. Such a system may provide direct measurement of substantially all of the external forces applied to the projection system or, at least, the most significant forces, namely those that result in the largest deformations of frame 10. Accordingly, from these measures, control system 30 may determine the expected deviation of beam of radiation B projected by the projection system with considerable accuracy.

It should be appreciated that, in an embodiment, force sensors 22 may be an integral part of mounts 15. This may, in particular, be the case if mounts 15 include actuators that may be used to adjust the position of the projection system. In such an arrangement, force sensors 22 may in any case be provided in order to control the actuators. Force sensors that are not integral to mounts 15 may alternatively or additionally be used.

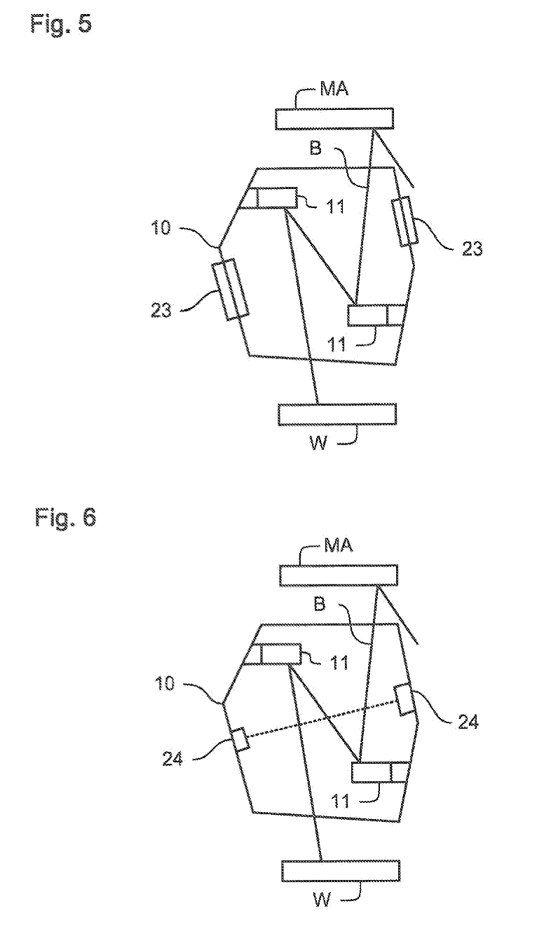

Alternatively or additionally, as depicted in FIG. 5, sensor system 20 may include one or more strain gauges 23 mounted to frame 10 of the projection system. It will be appreciated that such strain gauges 23 may directly measure deformations of frame 10, permitting control system 30 to determine the expected deviation of beam of radiation B projected by the projection system. In addition or as an alternative to the use of conventionally known strain gauges, sections of piezoelectric material may be mounted within or to frame 10 of the projection system and used to measure the strains of the frame.

Alternatively or additionally, as depicted in FIG. 6, sensor system 20 may include one or more sensor sets 24, such as interferometers, that are arranged to measure precisely the separation between two parts of frame 10 of the projection system. Such sensor sets 24 may provide accurate measurements of the overall deformation of the projection system, permitting a determination of the expected deviation of beam of radiation B projected by the projection system as a result of the deformations.

It will be appreciated that any combination of the above described sensors may be combined together to form sensor system 20. Likewise, other sensors may be used in order to provide measurements of alternative or additional parameters that are related to the deformation of frame 10 of the projection system.

As discussed above, control system 30 may be arranged in order to use the expected deviation of beam of radiation B from its intended location that is determined from the sensor system data in order to compensate for the deviation.

For example, as shown in FIG. 3, the projection system may include one or more actuators 41 that are configured to control the position of at least one of optical elements 11 used to correct beam of radiation B. It will be appreciated that by adjusting the position of at least one of the optical elements 11, the position of beam of radiation B projected by the projection system may, in turn, be adjusted. Accordingly, control system 30 may control at least one of actuator systems 41 in order to adjust the position of at least one of optical elements 11 such that the resulting movement of beam of radiation B projected by the projection system compensates for the expected deviation of the beam of radiation B caused by the deformation of frame 10. Consequently, beam of radiation B may be projected more accurately onto a desired target, such as a desired location on a substrate W.

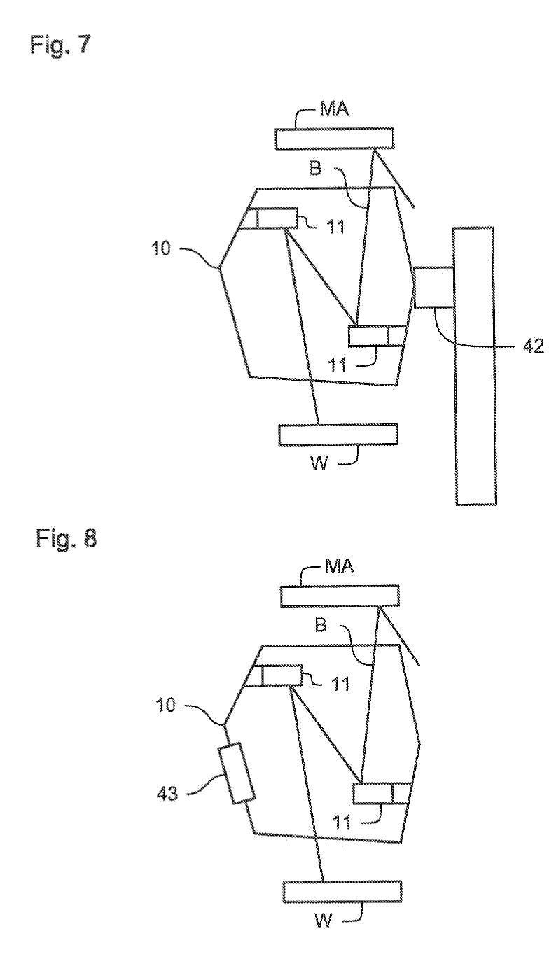

Alternatively or additionally, the position of the projection system relative to an apparatus to which it is mounted, such as a lithographic apparatus, may be controlled by an actuator system 42, as depicted in FIG. 7. Accordingly, control system 30 may be arranged to control actuator system 42 such that the overall position of the projection system is moved. The movement is such that it compensates for the expected deviation of beam of radiation B projected by the projection system. Accordingly, beam of radiation B may be projected more accurately onto a desired target, such as a portion of a substrate W. As discussed above, the actuators of actuator system 42 used to control the position of the projection system may be integral with the mounts that are used to support the projection system. Alternatively, the projection system may be mounted to the system that supports it by means of compliant mounts and separate actuators may be provided in order to control the position of the projection system.

Alternatively or additionally, as depicted in FIG. 8, frame 10 of the projection system may include an actuator system 43 that is configured to induced controlled deformations of frame 10 of the projection system. For example, actuator system 43 may be configured to provide forces between two parts of frame 10 such that frame 10 deforms in a controlled manner. Accordingly, control system 30 may be configured to determine a required deformation that can be induced by actuator system 43 that would result in a movement of beam of radiation B projected by the projection system that compensates for the expected deviation of beam of radiation B. The movement may be determined based on the data provided by sensor system 20. Accordingly, by providing a controlled deformation of frame 10 of the projection system using actuator system 43, beam of radiation B may more accurately be projected onto a desired target.

As discussed above, a projection system of an embodiment of the present invention may be utilized within a lithographic apparatus. Within such a lithographic apparatus, a support MT may be provided to support patterning device MA that imparts a pattern to beam of radiation B. Beam of radiation B may then be projected, using a projection system according to an embodiment of the present invention, onto a substrate W held on a substrate table WT.

In such an arrangement, control system 30 may alternatively or additionally be configured to control an actuator system PM that controls the position of patterning device MA in order to compensate for the expected deviation of beam of radiation B projected onto the substrate. In particular, movement of patterning device MA relative to beam of radiation B that is incident thereon may adjust the position of the pattern within the cross-section of the beam or radiation. Control system 30 may therefore adjust the position of the patterning device PM such that, although beam of radiation B may not be projected onto substrate W at precisely the desired location, the pattern that is projected onto the substrate is more accurately positioned relative to its desired location on the substrate.

Alternatively or additionally, control system 30 may be arranged to control an actuator system PW that is provided to control the position of substrate W in order to compensate for the expected deviation of beam of radiation B projected by the projection system onto substrate W. Accordingly, although beam of radiation B may be deviated from its intended position relative to the projection system, it is more accurately positioned relative to its desired location on substrate W.

It should be appreciated that control system 30 may be configured to use any combination of the arrangements discussed above for compensating for the expected deviation of beam of radiation B that is determined based on the measurements from sensor system 20.

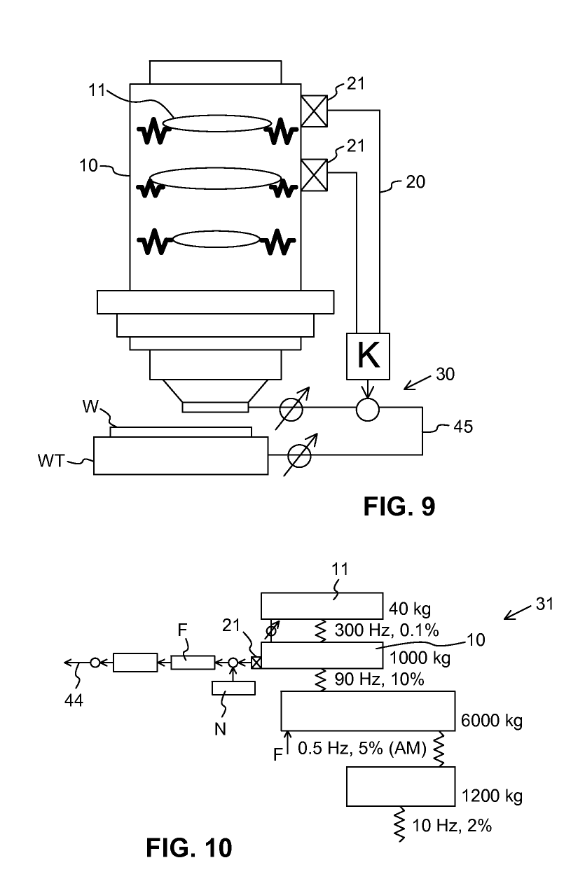

As explained above, and as depicted in FIG. 9, a projection system may include a relatively stiff frame 10 to which are mounted one or more optical elements 11 for directing a beam of radiation that has been patterned by a patterning device onto a substrate W. Ideally, projection system frame 10 may be accurately positioned within the lithographic apparatus relative to patterning device and substrate W and the one or more optical elements 11 may be accurately positioned relative to projection system frame 10, resulting in accurate transfer of the pattern from patterning device to substrate W. However, external forces induced by noise and scanning stages may act on the projection system, resulting in a displacement of the frame 10. As a result of such displacements, the optical elements 11 may be displaced relative to the frame and the beam of radiation that is projected onto substrate W may be projected onto the substrate at a location that is slightly shifted from its desired target location. In other words, the beam of radiation that is projected by the projection system may be deviated from an intended radiation beam path. The displacement of the optical elements 11 may result in a translation of the beam of radiation, the displacement of the projection system frame 10 may, alternatively or additionally, result in other deviations of the projection beam from its desired position. This may result in a deviation of the radiation wavefront at the substrate from that required to form a desired pattern on the substrate, resulting in, for example, focus errors or contrast errors.

Therefore, according to an embodiment of the present invention, a system such as that schematically depicted in FIG. 9 is provided. As shown, frame 10 of the projection system is provided with a sensor system 20 that measures at least one parameter, discussed further below, that relates to the displacement of the frame 10 that is generated by the external forces acting on the frame 10 whilst beam of radiation is projected onto substrate W. A control system 30 is provided that determines, from the measurement data from the sensor system 20, the deviation of beam of radiation from its intended location that would be caused by the displacement of the frame 10.

The expected deviation determined by control system 30 of the beam of radiation that is, for example, projected onto substrate W, may be used to ameliorate the effects of the displacement of the frame 10.

For example, as explained in more detail below, one or more corrections may be made based on the expected deviation of the beam of radiation. These corrections compensate for the expected deviation of the beam of radiation from an intended location such that beam of radiation is more accurately projected onto the desired location of substrate W.

Alternatively, or additionally, the expected displacement may be recorded. This may provide data that is useful, even if no steps are taken to compensate for the expected displacement. For example, by monitoring the expected displacement that is determined by the control system 30, operation of the projection system may continue while the expected displacement is within an acceptable limit but may be suspended if the expected displacement exceeds that limit. Likewise, monitoring of the expected displacement may be used to schedule maintenance operations of the projection system, for example in order to make corrections to the system before the expected displacement exceeds a tolerated extent. Similarly, monitoring the expected displacement of the location of projection beam from its desired target location on substrate W may be collated for each substrate and/or each device being formed on a substrate, such that the quality of formation of the devices may be graded.

Control system 30 may include a model 31 (see FIG. 10), such as a mathematical model that represents the lithographic apparatus. In particular, model 31 may relate the parameters measured by sensor system 20 to the displacements of optical elements 11. In turn, model 31 may relate the displacements of optical elements 11 to the expected displacement of the beam of radiation projected by the projection system. Accordingly, control system 30 may use a processor and model 31 in order to determine the expected displacement of the beam of radiation projected by the projection system, based on the measurement data from sensor system 20. The processor may then respond in a desired fashion, for example taking steps necessary to compensate for the expected displacement, as explained in more detail below.

Alternatively, or additionally, control system 30 may include a memory containing calibration data. The calibration data may directly relate the measurement data from sensor system 20 to the expected displacement of the beam of radiation projected by the projection system.

For example, the calibration data stored in the memory may be generated by performing a series of tests before the projection system is used in, for example, the manufacture of devices. Accordingly, a series of external forces may be applied to the projection system. For each loading condition, measurements may be taken and recorded by the sensor system. At the same time, direct measurements of the displacement of the beam of radiation projected by the projection system may be made. These measurements may be made by a Transmission Image Sensor (e.g., such as U.S. Pat. No. 7,675,605 assigned to ASML Netherlands B.V.) for measuring a position of an image produced with the projection system. This data may then be used as the calibration data.

In a particular embodiment of a projection system, such that depicted in FIG. 9, sensor system 20 may include one or more accelerometers 21 mounted to frame 10 of the projection system.

The one or more accelerometers 21 may be configured to measure the acceleration of the frame 10 of the projection system in, for example, all six degrees of freedom. However, it will be appreciated that this may not be necessary in order to improve the performance of the projection system. Accordingly, the one or more accelerometers 21 may measure the acceleration of the frame 10 in a more limited set of degrees of freedom.

The measured acceleration of one or more parts of frame 10 of the projection system will be related to the acceleration of the optical elements 11 and therefore to the displacements that will be induced in optical element 11 by those external forces. Accordingly, control system 30 may determine the displacement of the optical elements based on the measurement data from the one or more accelerometers 21. Controller 30 may then use that data to determine the expected displacement of the beam of radiation as described above.

The model in FIG. 10 depicts a lithographic apparatus with an optical element 11 mounted in the frame 10 with a suspension having a stiffness of 300 Hz. For low frequencies (<300 HZ) the optical elements displacements are proportional to the lens acceleration. The acceleration will be measured with the accelerometer 21. Disturbance noise N (from the accelerometer) will be added to this acceleration signal and both will be fed to a filter F for filtering the signal. The filtered signal 44 may be used to correct the relative substrate table measurement 45 (in FIG. 9).

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion,” respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that embodiments of the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 5-20 nm), as well as particle beams, such as ion beams or electron beams.

The term “lens,” where the context allows, may refer to any one or combination of various types of optical components, including refractive, reflective, magnetic, electromagnetic and electrostatic optical components.

While specific embodiments of the invention have been described above, it will be appreciated that embodiments of the invention may be practiced otherwise than as described. For example, embodiments of the invention may take the form of a computer program containing one or more sequences of machine-readable instructions describing a method as disclosed above, or a data storage medium (e.g., semiconductor memory, magnetic or optical disk) having such a computer program stored therein.

The descriptions above are intended to be illustrative, not limiting. Thus, it will be apparent to one skilled in the art that modifications may be made to the invention as described without departing from the scope of the claims set out below.

What is claimed is:

1. A projection system, configured to project a beam of radiation, comprising:
a frame configured to support at least one optical element that is used to direct at least a part of the beam of radiation;
a sensor system, configured to measure at least one parameter that relates to a displacement of the frame generated by forces applied to the frame during use of the projection system; and
a control system, configured to determine an expected deviation of the position of the beam of radiation projected by the projection system that is caused by said physical displacement of the frame using the measurements of the sensor system.

2. The projection system according to claim 1, wherein the control system includes a model of the projection system; and the control system determines the expected deviation of the position of the beam of radiation for measurement values from said sensor system by applying the measurement values from the sensor system to the model of the projection system and determining the response of the model.

3. The projection system according to claim 1, wherein the control system includes calibration data that relates previous measurement values of the sensor system to corresponding previously measured deviations of the position of the beam of radiation; and the control system determines the expected deviation of the position of the beam of radiation for measurement values from said sensor system using the calibration data.

4. The projection system according to claim 1, wherein said sensor system comprises at least one accelerometer, configured to measure the acceleration of a part of the projection system.

5. The projection system according to claim 4, wherein the control system uses data from said at least one accelerometer to generate measurement values of the forces applied to the projection system that would cause the measured acceleration; and the control system uses the measurement values of the forces to determine the expected deviation of the position of the beam of radiation.

6. The projection system according to claim 1, wherein the projection system comprises at least one mounting point, configured such that the projection system may be mounted within a system in which it is to be used by means of said at least one mounting point; and
said sensor system comprises a force sensor associated with said at least one mounting point configured to measure the force applied to the projection system through the mounting point.

7. The projection system according to claim 1, wherein said sensor system comprises at least one strain gauge mounted to said frame.

8. The projection system according to claim 1, wherein said sensor system comprises at least one sensor that is configured to measure the separation of two parts of said frame.

9. The projection system according to claim 1, further comprising an actuator system configured to control the position of at least one of said at least one optical element supported by said frame;
wherein the control system is configured to use said actuator system to adjust the position of said at least one optical element such that it compensates for the expected deviation of the beam of radiation projected by the projection system that is determined by the control system.

10. The projection system according to claim 1, further comprising an actuator system, configured to control the position of the frame relative to a system to which the projection system may be mounted;
wherein the control system is configured to use said actuator system to adjust the position of the frame such that it compensates for the expected deviation of the beam of radiation projected by the projection system that is determined by the control system.

11. The projection system according to claim 1, further comprising an actuator system, configured to induce controlled deformations of the frame;
wherein the control system is configured to use said actuator system to induce controlled deformation of the frame such that it compensates for the expected deviation of the beam of radiation projected by the projection system that is determined by the control system.

12. A lithographic apparatus, comprising:
a support constructed to support a patterning device that is capable of imparting a radiation beam with a pattern in its cross-section to form a patterned radiation beam;
a substrate table constructed to hold a substrate; and
a projection system according to claim 1, configured to project the patterned radiation beam onto a target portion of the substrate.

13. The lithographic apparatus according to claim 12, further comprising an actuator system configured to control the position of a patterning device supported by said support;
wherein the control system is configured to use said actuator system to adjust the position of the patterning device such that it compensates for the expected deviation of the beam of radiation projected by the projection system that is determined by the control system.

14. The lithographic apparatus according to claim 12, further comprising an actuator system configured to control the position of a substrate held on said substrate table;
wherein the control system is configured to use said actuator system to adjust the position of the substrate such that it compensates for the expected deviation of the beam of radiation projected by the projection system that is determined by the control system.

15. The lithographic apparatus according to claim 12, further comprising a memory configured to store data corresponding to the expected deviations of the position of the beam of radiation projected onto a substrate that are determined by the control system.

16. A method of projecting a beam of radiation onto a target, comprising:
directing the beam of radiation using at least one optical element that is supported by a frame;
measuring at least one parameter that relates to a displacement of the frame generated by forces applied to the frame while projecting the beam of radiation onto the target; and
determining an expected deviation of the position of the beam of radiation that is caused by said displacement of said frame using said measured at least one parameter.

17. A device manufacturing method comprising projecting a patterned beam of radiation onto a substrate using the method of claim 16 Projection System, Lithographic Apparatus, Method of Projecting a Beam of Radiation onto a Target and Device Manufacturing Method
